(19) United States
(12) Patent Application Publication
(10) Pub. No.: US 2024/0152479 A1
(43) Pub. Date: May 9, 2024

(54) METHOD FOR TRANSMITTING DATA ACCORDING TO A PROTOCOL COMPRISING A CLASS OF COMMUNICATION INTERFACE OBJECTS OF THE SERIAL PORT TYPE, AND ELECTRONIC DEVICE EXECUTING SAID METHOD

(71) Applicant: SAGEMCOM ENERGY & TELECOM SAS, Rueil Malmaison (FR)

(72) Inventors: Henri TEBOULLE, Rueil Malmaison (FR); Ziv ROTER, Rueil Malmaison (FR); Sylvestre ADAM, Rueil Malmaison (FR)

(73) Assignee: SAGEMCOM ENERGY & TELECOM SAS, Rueil Malmaison (FR)

(21) Appl. No.: 18/382,909

(22) Filed: Oct. 23, 2023

(30) Foreign Application Priority Data
Nov. 8, 2022 (FR) 2211594

(51) Int. Cl. G06F 13/42

(52) U.S. Cl. CPC G06F 13/4282; G06F 2213/0002

(57) ABSTRACT

A method for transmitting data from and to an electronic device configured to implement at least transmissions of metering data on consumption of a physical quantity, said transmissions being implemented by said electronic device according to at least one data communication protocol (for example DLMS/COSEM) referring to data defined according to an object oriented data model, said data model defining a plurality of classes of communication interface objects, making it possible to access elements of the electronic device, said method being such that said object oriented data model comprises at least one class of communication interface objects comprising attributes and methods for implementing communications via a communication port of the serial port type included in said electronic device or connected thereto. The invention also relates to an electronic device implementing the method.

### TECHNICAL FIELD

The present invention relates to a communication method able to make data transmissions defined according to an object-oriented data model, from and to an electronic device configured for collecting consumption data of a physical quantity. At least one embodiment of the invention relates to a method for transmitting data via a serial port of an electricity consumption smart meter.

### PRIOR ART

Recent electricity consumption meters are so-called “smart” electronic devices able to transmit data to a remote server, for example a consumption-management server, through varied communication networks, in particular for pricing and information-collecting services in relation to electricity consumption. These smart meters are further configured to receive data from a remote server. Such information received by a smart meter is in particular useful for configuration thereof, for example to limit the maximum power that can be delivered through this smart meter, or for switching an internal electrical contact to the smart meter. Communication protocols have been defined for communicating with a smart electricity consumption meter, by exchanging messages (data transmissions) the format of which is independent of the physical configuration of the network or networks used for transmitting these messages. Among these protocols, the so-called “DLMS” (the abbreviation of “Device Language Message Specification”) protocol and the “COSEM” (the English acronym for “Companion Specification for Energy Metering”) data protocol model are used for electricity consumption metering applications, independent of the communication medium, relying in particular on a client-server principle according to which a smart meter operates as a data server. According to this principle, an electricity consumption smart meter is a so-called “COSEM server” and is modelled by a set of logical devices, implemented in a physical electronic device that is the smart meter. According to the DLMS/COSEM protocol, a logical device of a COSEM server is a set of COSEM communication interface objects that each model various functions of the physical meter and are accessible to a so-called “client” device connected to the smart meter operating as a “server” via a communication network, by means of communication interfaces of the smart meter. Such an interface object has “attributes” and “methods” that can be invoked to communicate with such a smart meter. An interface structure is defined and described uniquely in a class of communication interfaces (or class of communication interface objects) that is specified and standardised according to the protocol.

The attributes represent the characteristics of the object, for example such attributes may be configuration parameters of a communication interface (an interface also usually referred to as a “port”). An attribute may also be a register of a smart meter containing a power value consumed during a predetermined period. The methods as defined in the DLMS protocol and according to the COSEM object-oriented data model make it possible to manipulate an object for accessing the values of its attributes, in read mode and/or in write mode. In other words, a method according to the DLMS protocol is a function for access, in read mode or in write mode, to an attribute of an object such as, for example, a communication interface object. The classes of communication interface objects thus defined in the DLMS/COSEM protocol, or according to other similar protocols, constitute communication tools that a manufacturer of metering equipment (or more broadly of equipment connected to an energy distribution network), can use during design steps and for providing functionalities available from a smart meter or involving transmissions of data via such a meter, or from equipment connected to an energy distribution network. There do not however exist means for implementing communications between a remote server or any remote item of equipment and a high-speed asynchronous serial port included in a smart meter or connected thereto, which limits the applications and services able to be deployed via the existing means of communication between such a server/equipment and an electronic device implementing smart-meter functions, or more broadly between such a server/equipment and remote equipment connected to one and the same electricity distribution network. However, such a serial port, for example of the RS-422 or RS-485 type, offers a good compromise between its characteristics of transmission speed and transmission reliability, and its simplicity of use (little cabling).

The situation can be improved.

### DISCLOSURE OF THE INVENTION

The aim of the invention is to propose a method for transmitting messages via a DLMS protocol to provide an end-to-end service between an energy supplier or service provider on the one hand and an end user (a subscriber of the supplier and/or of the service provider) on the other hand, the service using a high-speed asynchronous serial port at the subscriber to control one or more actuators and/or to collect information from one or more sensors installed at this subscriber.

For this purpose, a method is proposed for transmitting data from and to an electronic device configured to implement at least transmissions of metering data on consumption of a physical quantity, said transmissions being implemented by said electronic device according to at least one data communication protocol referring to data defined according to an object oriented data model, said data model defining a plurality of classes of communication interface objects, each of said classes of objects defined according to said model comprising a set of attributes representing characteristics of an object defined according to said class, as well as a set of methods for accessing values of said attributes, said method being executed in said electronic device or in a remote server connected to said electronic device and being characterised in that said object oriented data model comprises at least one class of communication interface objects comprising attributes and methods for implementing communications via a communication port of the serial port type included in said electronic device or connected thereto.

The method according to the invention may also comprise the following features, considered alone or in combination:
The object-oriented data model is a COSEM model derived from the COSEM model (IEC 62056-6-2: 2017.
The at least one communication protocol is a DLMS protocol in the IEC 62056 standardised protocol set.
The at least one class of communication interface objects comprises attributes and methods for implementing communications by means of a serial port of the asynchronous type.
The attributes and the methods are configured to implement communications with an asynchronous serial port defined according to a so-called RS-422 communication standard or a so-called RS-485 communication standard.
The set of methods comprises a method for obtaining a number of bytes available in read mode in a buffer of the serial port, a method for writing a predetermined series of bytes in a buffer in transmission mode of the serial port or a method for reading a series of bytes available in a buffer in reception mode of the serial port.
The at least one class of communication interface objects comprises attributes and methods for implementing communications with a serial port of the asynchronous type.

Another object of the invention is an electronic device configured to implement at least transmissions of metering data on consumption of a physical quantity, the transmissions being implemented by the electronic device according to at least one data communication protocol referring to data defined according to an object oriented data model, the data model defining a plurality of classes of communication interface objects, each of the classes of objects defined according to said model comprising a set of attributes representing characteristics of an object defined according to said class, as well as a set of methods for accessing values of the attributes, the electronic device being such that the object oriented data model comprises at least one class of communication interface objects comprising attributes and methods for implementing communications via a serial port included in the electronic device connected thereto.

The electronic device according to the invention may also comprise the following features, considered alone or in combination:
The device is configured to use an object-oriented data model that is a COSEM model derived from the COSEM model (IEC 62056-6-2: 2017.
The electronic device is configured to use at least one DLMS communication protocol in the IEC 62056 standardised protocol set.
The electronic device is configured to use at least one class of communication interface objects comprising attributes and methods for implementing communications with a serial port of the asynchronous type, preferentially of the type defined according to a so-called RS-422 communication standard or a so-called RS-485 communication standard
The electronic device is an electricity consumption meter or a residential gateway configured for connecting an electricity consumption meter to a powerline communication network.

Another object of the invention is a communication system comprising at least one electronic device as previously described and a remote server, configured to be connected to each other via a communication network.

Finally, the invention relates to a computer program product comprising program code instructions for performing the steps of the method described above when this program is executed by a processor of an electronic device as aforementioned or by a processor of a remote server configured to be connected to said electronic device, as well as a storage device comprising such a program.

### BRIEF DESCRIPTION OF THE DRAWINGS

The features of the invention mentioned above, as well as others, will emerge more clearly from the reading of the following description of at least one example embodiment, said description being made in relation to the accompanying drawings, among which:

FIG. 1 illustrates schematically a communication network comprising an electronic device configured to execute a data transmission protocol according to one embodiment;

FIG. 2 illustrates elements of a class of communication interface objects defined according to a communication protocol executed in the communication network already illustrated on FIG. 1, according to one embodiment;

FIG. 3 is a flow diagram illustrating steps of a data transmission method using at least one interface object instanced with reference to the class of communication interface objects shown on FIG. 2;

FIG. 4 is a diagram illustrating an internal architecture of an electronic device, for example of the smart meter type, configured to execute a data transmission protocol according to one embodiment;

FIG. 5 is a diagram illustrating an internal architecture of a server of a service provider configured to execute a data transmission method according to one embodiment;

FIG. 6 is a time representation of data transmissions in the form of messages between a server and a domestic installation connected to a smart meter in an application for remote control of the charging of a battery, using a communication protocol according to one embodiment; and

FIG. 7 is a time representation of data transmissions in the form of messages between a server and a domestic installation connected to a smart meter in an application for remote control of an intruder alarm, using a communication protocol according to one embodiment.

### DETAILED DISCLOSURE OF EMBODIMENTS

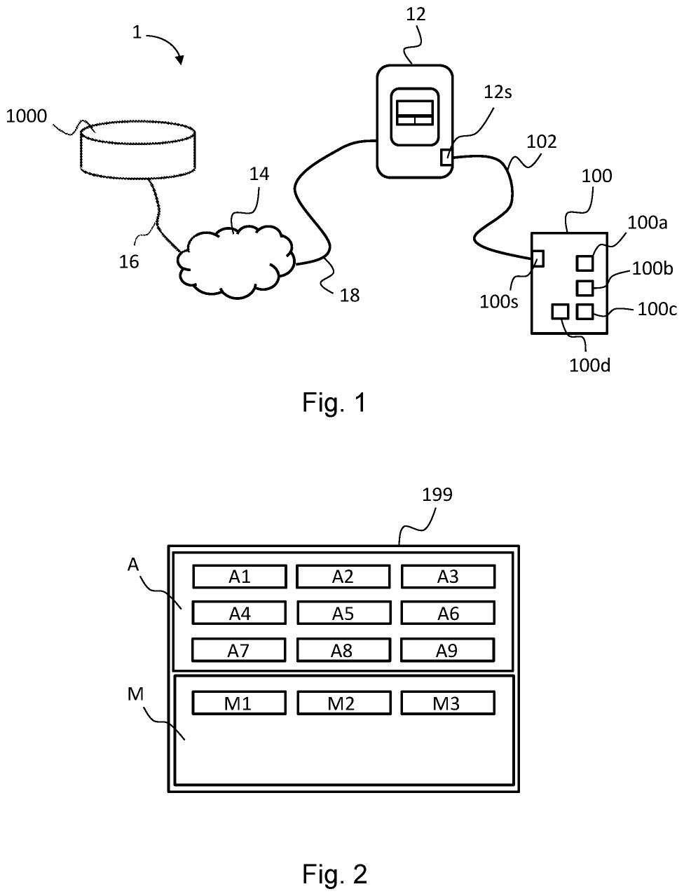

FIG. 1 illustrates schematically a communication network 1 comprising a powerline communication network 14, to which there are connected a server 1000 of a service provider and an electronic device 12 configured to mainly execute meter functions for consumption of a physical quantity (water, electricity, gas, etc). According to the example described, the electronic device 12 is a so-called “smart” electricity consumption meter configured in particular to implement data transmissions via the communication network 14. The server 1000 of a service provider, also here called a “remote server”, is connected to the communication network 14 via an interface link 16. The electronic device 12, here of the electricity-supply smart meter type, is connected to the communication network 14 via an interface link 18. The electronic device 12 advantageously comprises an asynchronous serial port 12s configured to connect a domestic installation 100 to the electronic device 12 via a serial connection link 102. To do this, the domestic installation 100 comprises an asynchronous serial port 100s that can be configured to implement communications with the asynchronous serial port 12s of the electronic device 12. According to one embodiment, the serial ports 12s and 100s are of the RS-422 type. According to a variant embodiment, the serial ports 12s and 100s are of the RS-485 type. The domestic installation 100 is for example a home-automation installation. According to the example embodiment described, the domestic installation 100 comprises a supervised battery-recharging terminal and an intruder alarm. These examples are not limitative and the domestic installation 100 may comprise, according to variants, a wide variety of devices, in particular of the sensor or actuator type implemented to fulfil any functions (monitoring of goods, safety of persons, assistance, optimisation of energy consumption, etc). The battery-recharging terminal of the domestic installation 100 comprises a battery-charging controller 100a and a battery-connection relay 100b configured to allow or to interrupt the charging of the battery present in the domestic installation 100. The intruder alarm of the domestic installation 100 comprises in particular an intrusion detector 100c and a siren 100d.

According to one embodiment, the remote server 100 and the electronic device 12 are configured to be able to implement data transmissions, for example data on metering of consumption of a physical quantity, according to at least one data communication protocol referring to data defined according to an object oriented data model. Furthermore, the data model used defines a plurality of classes of communication interface objects, and each of these classes of objects defined according to the model comprises a set of attributes representing characteristics of an object defined according to this class, as well as a set of methods for accessing values of these attributes, in read mode and/or in write mode.

Cleverly and advantageously, the communication method used implemented in the electronic device 12 or in a remote server connected to the electronic device 12, such as the remote server 1000, comprises at least one class of communication interface objects 199 comprising attributes and methods for implementing transmissions via a communication port of the serial port type included in the electronic device 12 or connected to the electronic device 12 such as the serial port 12s.

FIG. 2 describes the class of interface objects 199, which can be referenced via a unique identifier Class Id of a class of interface objects in a communication protocol, and optionally by a version number Version Id. Advantageously, the class of interface objects 199 comprises attributes and methods for implementing communications via a communication port of the serial port type, asynchronous and high speed. The class of interface objects 199 comprises a set A of attributes and a set M of methods. The set A of attributes comprises attributes A1, A2, A3, A4, A5, A6, A7, A8 and A9 useful to the configuration of a high-speed asynchronous serial port such as the physical serial port 12s of the electronic device 12. The set M of methods comprises methods M1, M2, and M3 useful to data transmissions from and to a high-speed asynchronous serial port such as the physical serial port 12s of the electronic device 12.

In the example described, the attributes A1, A2, A3, A4, A5, A6, A7, A8 and A9 of the set of attributes A of the class of interface objects 199 are respectively associated with characteristics (operating parameters) of a physical asynchronous serial interface (also commonly referred to as “serial port”) such as:
The attribute A1, of rank 1 in the class of interface objects 199, determines a logical name logical name of a serial port instanced from this class, in the form of a string of alphanumeric characters;
The attribute A2, of rank 2 in the attributes of the class of interface objects 199, determines a transmission speed value baudrate via a serial port instanced from this class;
The attribute A3, of rank 3 in the attributes of the class of interface objects 199, determines a code databits defining a number of databits used for coding data during a transmission of data via a serial port instanced from this class;
The attribute A4, of rank 4 in the attributes of the class of interface objects 199, determines a code stopbits defining a number of stop bits used for coding data during a transmission of data via a serial port instanced from this class;
The attribute A5, of rank 5 in the attributes of the class of interface objects, determines a code parity defining a transmission mode with parity bit or bits or without parity bit via a serial port instanced from this class;
The attribute A6, of rank 6 in the attributes of the class of interface objects 199, determines a code flowcontrol defining a transmission mode with or without flow control via a serial port instanced from this class;
The attribute A7, of rank 7 in the attributes of the class of interface objects 199, determines a maximum size txtbuffer size of transmission buffer for transmission via a serial port instanced from this class;
The attribute A8, of rank 8 in the attributes of the class of interface objects 199, determines a code ending byte defining a content state (number of bytes available for example) of a buffer of a serial port instanced from this class;
The attribute A9, of rank 9 in the attributes of the class of interface objects 199, determines a state flowcontrol state of a flow control mechanism (or circuit) for data transmissions via a serial port instanced from this class.
Still according to the example described, the methods M1, M2 and M3 of the set of methods B of the class of interface objects 199 are respectively associated with functions (configuration or data-transmission operations) of an asynchronous serial interface (also commonly referred to as “serial port”) such as:
The method M1, of rank 1 in the methods of the class of interface objects 199, implements an initialisation or a reinitialisation reset (data) of the attributes A1 to A9 of the buffers in transmission mode and in reception mode, as well as all or some of the operating circuits internal to a serial port instanced from this class, by allocating where applicable default values to attributes;
The method M2, of rank 2 in the methods of the class of interface objects 199, implements a data transmission send bytes (data) of a string of data data from a serial port instanced from this class to a device connected to this serial port, via an electronic device comprising said serial port;
The method M3, of rank 3 in the methods of the class of interface objects 199, implements a data transmission receive bytes (data) of a string of data data from a serial port of an electronic device, instanced from this class, coming from a device connected to this serial port.

According to one embodiment, the attributes of the object oriented data model of the class of interface objects 199 are defined such that:
the attribute A1 is a character string with a predetermined maximum size;
the attribute A2 can take a value from the values 0 to 10 corresponding respectively to a rate of 300 baud, 1200 baud, 2400 baud, 4800 baud, 9600 baud, 19,200 baud, 38,400 baud, 57,600 baud, 115,200 baud, 230,400 baud and 460,800 baud;
the attribute A3 can take a value from the values 0 to 4 corresponding respectively to 5 data bits, 6 data bits, 7 data bits, 8 data bits and 9 data bits per data word;
the attribute A4 can take a value from the values 1, 1.5 and 2, corresponding to the number of stop bits positioned at the end of a data word;
the attribute A5 can take a value from the values 0 to 4 corresponding respectively to an absence of calculation of parity on a data word referred to as “NO PARITY”, to a parity of the even type referred to as “EVEN”, to a parity of the odd type referred to as “ODD”, to a parity of the so-called “MARK” type or to a parity of the so-called “SPACE” type;
the attribute A6 can take a value from the values 0 to 2 corresponding respectively to an absence of flow control referred to as “No Flow Control”, to a hardware flow control of a so-called “RTS/CTS” type, from the English “Ready To Send” and “Clear To Send”, or to a software flow control of a so-called “XON/XOFF” type;
the attribute A7 takes a value defining a maximum buffer size in transmission mode;
the attribute A8 takes the value of a number of data words available in reception mode in a buffer in reception mode, and
   the attribute A9 takes a value among the values 0 to 1 corresponding respectively to an available state known as “clear” and an occupied state known as “busy” of the serial port in transmission mode.

According to one embodiment, the methods of the object oriented data model of the class of interface objects 199 are defined such that:
A data parameter equal to 0 of the method reset (data) M1 re-initialises the buffers in transmission mode and in reception mode of the serial port by filling them with zero (0) values of the integer type;
The method M2 send bytes (data) implements a transmission of a string of coded characters in the form of bytes to an instanced serial port;
The method M3 receive bytes (data) implements a reception of data in the form of a string of characters with as parameter a maximum number data of data that a COSEM client can read from an instanced serial port of an electronic device comprising this serial port.

The definition of the class of interface objects 199 as aforementioned advantageously makes it possible to control the serial port 12s embedded in the electronic device 12, from the remote server 1000, using the DLMS data transmission protocol and the COSEM data model, or an equivalent protocol using the class of interface objects 199.

According to one embodiment, a device comprising a remotely controllable serial port after an instancing of the class of interface objects 199 comprises an internal electronic circuit (or controller) of the control interpreter type, for translating first commands into second commands and then sending the second commands via the physical serial port to devices of the controllable actuator or sensor type. For example, a series of bytes sent by the remote server 1000 into the buffer in transmission mode of a serial port of the electronic device 12, while invoking a serial-port object defined and instanced according to the class of interface objects 199, is next interpreted by the electronic device 12 as a command for initialising actuators of the domestic installation 100, and one or more commands stemming therefrom are sent accordingly from the electronic device 12 to the domestic installation 100.

Advantageously and by virtue of the remote controlling of the serial port 12s of the electronic device 12 thus made possible, a service provider can offer services to a subscriber to an energy supply or fluid supply service (electricity, water, gas, etc) having a smart meter such as the electronic device 12. According to the example described, a service provider can, by means of the remote server 1000, implement applications controlling the serial port 12s of the electronic device 12 of the smart consumption meter type and therefore, consequently, control all or part of a domestic (or home-automation) installation such as the domestic installation 100.

Cleverly, and since a device operating in the capacity of COSEM server does not spontaneously send data to a COSEM client device, as the remote server 1000 executing applications with a view to remotely controlling the domestic installation 100 through the communication network 1 and the electronic device 12 may be, it is proposed here to create objects in the class of interface objects 159, making it possible to initiate or more broadly to organise data transmissions between the remote server 1000 operating for example as a COSEM client, and the domestic installation 100 via the electronic device 12 and its serial port 12s.

An object “MONITOR” is here proposed and configured to read a number of bytes waiting to be read in a buffer (in reception mode) of the serial port 12s instanced from the class of interface objects 199, and which has as attribute a threshold of triggering of the reading, as soon as a minimum number of available bytes is reached.

An object “PUSH Setup” is also proposed here, and which comprises a method called “PUSH”, said object “PUSH Setup” comprising a list of objects “PUSH Object List” pointing to objects, for example COSEM objects, which must be sent to a client, for example a COSEM client, such as the server 1000.

Thus a serial-port logical device instanced from the class of interface objects 199 in the electronic device 12 enables a service provider operating from the remote server 1000 to read data referenced in a buffer zone associated with the PUSH method on the one hand and to write data to the serial port 12s on the other hand.

A data reader referenced in the buffer of the PUSH method, by the remote server 1000, uses the method M3 receive bytes of the serial port instanced from the class of interface objects 199.

In the same way, a writing of data to the serial port, by the remote server 1000, uses the method M2 send bytes of the serial port instanced from the class of interface objects 199.

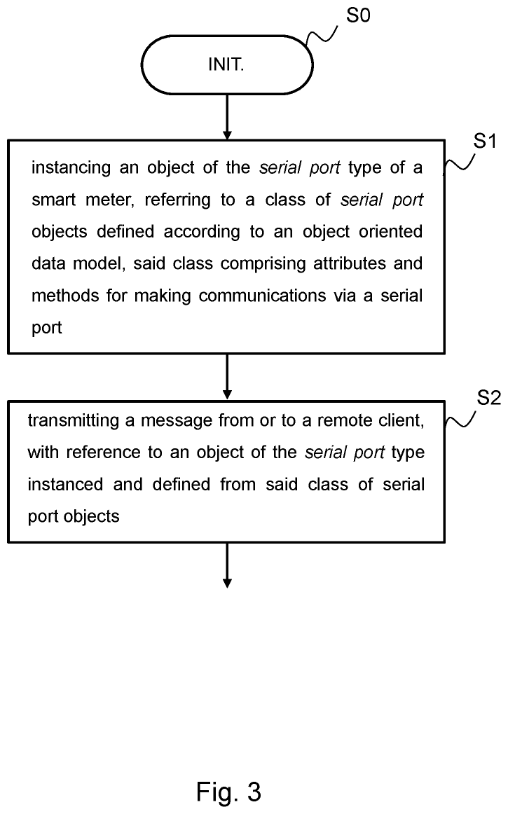

FIG. 3 illustrate steps of a data transmission method for instancing a logical device of the serial port type, for example of the RS-422 type or of the RS-485 type, to control a physical serial port of the same type as the electronic device 12 configured to make data transmissions with the remote server 1000 using a data exchange protocol based on an object oriented data model. According to the example described, the server 1000 operates as application server of a service provider and is configured to make data transmissions using a so-called agnostic DLMS/COSEM protocol (i.e. making data transmissions without any consideration of the physical format of the communication network or networks used). Still according to the example described, the electronic device 12 is also configured to make data transmissions using a so-called agnostic DLMS/COSEM protocol. The electronic device 12 here fulfils functions of DLMS/COSEM data server.

A step S0 corresponds to an initialisation step at the end of which the remote server 1000 and the electronic device 12 are both normally configured to make data transmissions through the powerline communication network 14, which is also an electricity distribution network.

In a step S1, the electronic device 12 detects the presence of the physical serial port 12s, native or installed during a maintenance or upgrade operation subsequent to commissioning thereof, and instances an object of the logical serial port type as defined according to the class of interface objects 199, so that this logical object can be addressed by means of the attributes and methods defined according to an object oriented data model such as the COSEM data model, by a device connected to the powerline communication network 14. The physical serial port corresponding to this instancing can then be controlled by modifying the attributes of the logical serial port instanced. It should be noted that there can be as many logical serial ports instanced as there exist physical serial ports in the electronic device 12 or connected thereto.

In a step S2 a transmission of data between the remote server 1000 and the electronic device 12 makes a reading or a writing of data from or to the serial port 12s, invoking a method from all the methods M for modifying the attributes of the set of attributes A of the logical serial port instanced and enabling accordingly a configuration or reconfiguration of the serial port 12s or a transmission of data between the remote server 1000 and the serial port 12s of the electronic device 12 or, where applicable, between the serial port 12s and the domestic installation 100.

Obviously, a logical serial port instanced from the class of interface objects 199 can be addressed via a data exchange protocol other than the DLMS protocol using the COSEM data model, provided that this protocol is adapted to perform operations on such an object defined according to the class of interface objects 199.

According to a preferred embodiment, the data exchanges between the remote server 1000 and the electronic device 12 are made in accordance with a DLMS/COSEM protocol and the powerline communication network operates according to a set of protocols of the G3-PLC type.

FIG. 6 illustrates schematically a sequencing of operations implemented by means of message transmissions between the remote server 1000, operating as an application server of a service provider and the domestic installation 100 advantageously connected to the serial port 12 of the electronic device 12. According to the example described in relation to FIG. 6, the domestic installation 100 is configured to implement functions of a battery charging station (also called a terminal) by means of the battery charging controller 100a and the battery-connection relay 100b. According to the example described here, a provider of services for home-charging of the battery, for example a battery of an electric or hybrid car, provides monitoring and management of the charging of the battery connected to the domestic installation 100. For example, the domestic installation 100 comprises a terminal for recharging electric vehicles of the bicycle, motorcycle or car type.

In the example developed below, a data transmission between the remote server 1000 and the electronic device 12, or a data transmission between the device 12 and the domestic installation 100, via the serial port 12s, the serial link 102 and the serial port 100s, is called a “message” and corresponds to a data transmission according to a first protocol, of the DLMS/COSEM type, between the remote server 1000 and the electronic device 12, and according to a second protocol, proprietary or standardised, between the electronic device 12 and the domestic installation 100.

A battery-charging management application, executed in the remote server 1000, sends a message 61 to the electronic device 12, said message comprising a request to read registers of operating parameters of the charging controller 100a. The registers concerned contain data given by a control unit internal to the charging controller 100a. These data are a charging voltage V, a charging current I and a temperature 0 measured at a point of a battery under charge, as well as a charging status S of the battery expressed as a charge percentage. This request is relayed by the device 12, via its serial port 12s, to the charging controller 100a in a message 62. The charging controller 100a then sends, to the serial port 12s of the electronic device 12, successive messages 63, 64, 65 and 66 comprising respectively the values of V, I, 0 and S. The electronic device 12 sends its elements in a message 67 to the remote server 1000. The charging-management application executed on the remote server 1000 reads its information. In the case illustrated, the temperature 0 read exceeds a predetermined temperature threshold, referred to as “safety temperature Os”, and the server 1000, under control of the charging application that it executes, sends a message 68 to the electronic device 12 comprising a charging-interruption request, said request being relayed by the electronic device 12 via its serial port 12s in a message 69 sent to the battery-connection relay 100b of the domestic installation 100 in order to make a disconnection of the battery subsequent to the detection of an excessively high temperature 0 of the battery, said excessively high temperature being liable to cause damage.

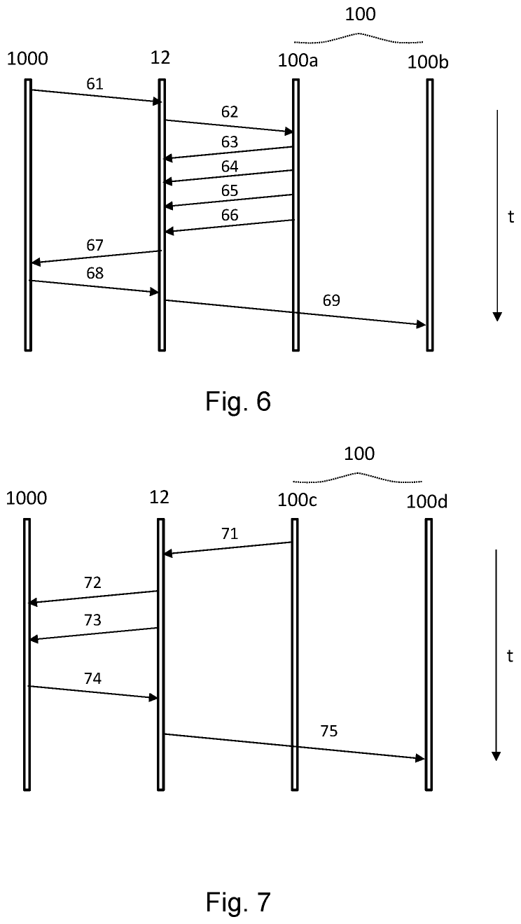

FIG. 7 illustrates schematically another sequence of operations implemented by means of message transmissions between the remote server 1000, there are also operating as an application server of a service provider and the domestic installation 100 advantageously connected to the serial port 12s of the electronic device 12. According to the example described in relation to FIG. 7, the domestic installation 100 is configured to operate intruder-alarm functions. According to the example described, a provider of a remote-monitoring service provides remote monitoring of the dwelling or of the room in which the domestic installation 100 is located by means of an intrusion detector 100c and enables in particular the triggering of a siren 100d according to a predefined protocol. In this example also, a data transmission between the remote server 1000 and the electronic device 12, or a data transmission between the device 12 and the domestic installation 100, via the serial port 12s, the serial link 102 and the serial port 100s, is called a “message” and corresponds to a message according to a first protocol, of the DLMS/COSEM type, between the remote server 1000 and the electronic device 12, and according to a second protocol, proprietary or standardised, between the electronic device 12 and the domestic installation 100.

According to the sequencing described, the intrusion detector 100c is activated by the effect of an intrusion and sends a message 71 to the electronic device 12 via its serial port 12s, mentioning that information representing a change of state of the intrusion detector 100c is available. The electronic device 12 then sends, to the remote server 1000 executing a remote-monitoring application, information notifying the change of state of the intrusion detector 100c, in a message 72. The remote server 100 then reads the state of the intrusion detector 100c via a message 73 and sends to the electronic device 12 a message 74 comprising a request to activate the siren 100d, said request being relayed by the electronic device 12 to the siren 100d via a message 75. At the same time as the triggering of the siren 12d, the service provider can undertake any action useful to the protection of the dwelling or of the room comprising the domestic installation 100.

In order to implement the data transmission methods described, the remote server 1000 and the electronic device 12 of the smart meter type each comprise electronic circuits configured to implement in particular control-unit and communication-interface functions.

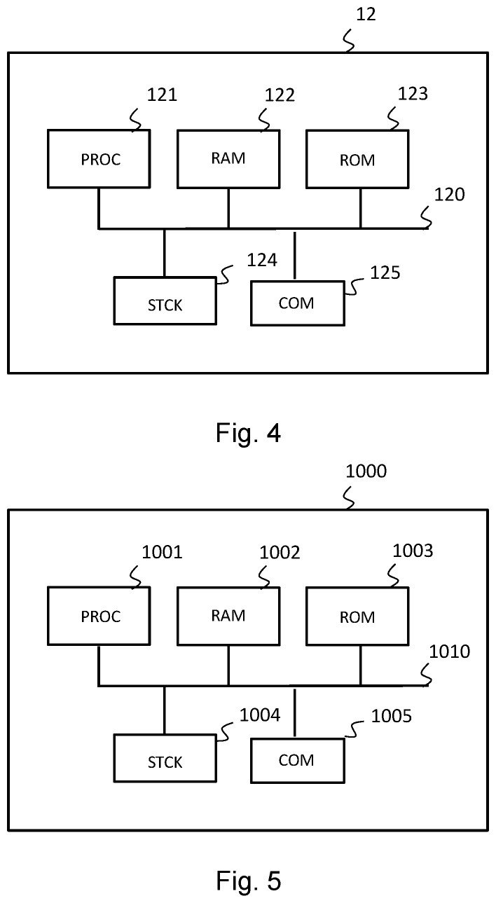

FIG. 4 illustrates schematically an example of internal architecture of the electronic device 12, of the smart meter type. According to the example of hardware architecture shown in FIG. 4, the smart meter 12 then comprises, connected by a communication bus 120: a processor or CPU (“central processing unit”) 121; a random access memory (RAM) 122; a read only memory (ROM) 123; a storage unit such as a hard disk (or a storage medium reader, such as an SD (Secure Digital) card reader 124); at least one communication interface 125 enabling the smart meter 12 to communicate with devices present in the communication network 1 and comprising the remote server 1000. The communication interface 125 furthermore comprises the serial port 12s.

The processor 121 is capable of executing instructions loaded in the RAM 122 from the ROM 123, from an external memory (not shown), from a storage medium (such as an SD card), or from a communication network. When the electronic device of the smart meter 12 type is powered up, the processor 121 is capable of reading instructions from the RAM 122 and executing them. These instructions form a computer program causing the implementation, by the processor 121, of the method described in relation to FIG. 3, and more broadly a data-transfer method such as a DLMS/COSEM protocol, one of the variants thereof or an equivalent protocol.

All or part of the method implemented by the smart meter 12, or the variants thereof described, can be implemented in software form by executing a set of instructions by a programmable machine, for example a DSP (“digital signal processor”), or a microcontroller, or be implemented in hardware form by a machine or a dedicated component, for example an FPGA (field-programmable gate array) or an ASIC (application-specific integrated circuit). In general, the smart meter 12 comprises electronic circuitry configured for implementing the method described in relation to it as well as with devices connected to the communication network 1. Obviously, the smart meter 12 further comprises all the elements usually present in a system comprising a control unit and its peripherals, such as a power supply circuit, a power-supply monitoring circuit, one or more clock circuits, a reset circuit, input/output ports, interrupt inputs and bus drivers, this list being non-exhaustive.

FIG. 5 illustrates schematically an example of internal architecture of the server 1000, also referred to here as the management server of a service provider.

According to the example of hardware architecture shown in FIG. 5, the server 1000 then comprises, connected by a communication bus 1010: a processor or CPU (“central processing unit”) 1001; a random access memory (RAM) 1002; a read only memory (ROM) 1003; a storage unit such as a hard disk (or a storage medium reader, such as an SD (Secure Digital) card reader 1004); at least one communication interface 1005 enabling the server 1000 to communicate with devices present in the communication network 1 and furthermore comprising the electronic device 12 and its serial port 12s.

The processor 1001 is capable of executing instructions loaded in the RAM 1002 from the ROM 1003, from an external memory (not shown), from a storage medium (such as an SD card), or from a communication network. When the server 1000 is powered up, the processor 1001 is capable of reading instructions from the RAM 1002 and executing them. These instructions form a computer program causing the implementation, by the processor 1001, of the method described in relation to FIG. 3, and more broadly a data-transfer method such as a DLMS/COSEM protocol, one of the variants thereof or an equivalent protocol.

All or part of the method implemented by the server 1000 or the variants thereof described, can be implemented in software form by executing a set of instructions by a programmable machine, for example a DSP (“digital signal processor”), or a microcontroller, or be implemented in hardware form by a machine or a dedicated component, for example an FPGA (field-programmable gate array) or an ASIC (application-specific integrated circuit). In general, the server 1000 comprises electronic circuitry configured for implementing the method described in relation to it as well as with devices connected to the communication network 1. Obviously, the server 1000 further comprises all the elements usually present in a system comprising a control unit and its peripherals, such as a power supply circuit, a power-supply monitoring circuit, one or more clock circuits, a reset circuit, input/output ports, interrupt inputs and bus drivers, this list being non-exhaustive.

The invention is not limited solely to the embodiments and examples described above, but relates more generally to a communication protocol using an object oriented data model and comprising a class of interface objects defining a serial port, in particular of the high-speed asynchronous serial port type.

1. A method for transmitting data from and to an electronic device configured to implement at least transmissions of metering data on consumption of a physical quantity, said electronic device comprising an internal electronic circuit of the command interpreter type, said transmissions being implemented by said electronic device according to at least one data communication protocol referring to data defined according to an object oriented data model, said data model defining a plurality of classes of communication interface objects, each of said classes of objects defined according to said model comprising a set of attributes representing characteristics of an object defined according to said class, as well as a set of methods for accessing values of said attributes in read mode and/or in write mode, said method being executed in said electronic device or in a remote server connected to said electronic device and wherein said object oriented data model comprises at least one class of communication interface objects comprising attributes and methods for implementing data transmissions via a communication port of the serial port type included in said electronic device or connected thereto, and in that first commands, received in the form of a series of bytes, in a buffer in transmission mode of said communication port of the serial port type, are translated by the command interpreter into second commands and sent via said communication port of the serial port type to devices of actuator or sensor types.

2. The data transmission method according to claim 1, wherein said object-oriented data model is a COSEM model derived from the COSEM model according to IEC 62056-6-2: 2017.

3. The data transmission method according to claim 2, wherein at least one communication protocol is a DLMS protocol in the standardised protocol set according to IEC 62056.

4. The data transmission method according to claim 1, wherein at least one class of communication interface objects comprises attributes and methods for implementing communications by means of a serial port of the asynchronous type.

5. The data transmission method according to claim 4, wherein said attributes and said methods are able to implement communications with an asynchronous serial port defined according to a so-called RS-422 communication standard or a so-called RS-485 communication standard.

6. The data transmission method according claim 1, wherein said set of methods comprises a method for obtaining a number of bytes available in read mode in a buffer of the serial port, a method for writing a predetermined series of bytes in the buffer in transmission mode of the serial port or a method for reading a series of bytes available in a buffer in reception mode of the serial port.

7. The data transmission method according claim 1, wherein at least one class of communication interface objects comprises attributes and methods for implementing communications by means of a serial port of the asynchronous type.

8. An electronic device configured to implement at least transmissions of metering data on consumption of a physical quantity, said electronic device comprising an internal electronic circuit of the command interpreter type, said transmissions being implemented by said electronic device according to at least one data communication protocol referring to data defined according to an object oriented data model, said data model defining a plurality of classes of communication interface objects, each of said classes of objects defined according to said model comprising a set of attributes representing characteristics of an object defined according to said class, as well as a set of methods for accessing values of said attributes in read and/or write mode, said electronic device wherein said object oriented data model comprises at least one class of communication interface objects comprising attributes and methods for implementing communications by means of a serial port included in said electronic device or connected thereto, and in that the internal electronic circuit of the command interpreter type is configured to translate first commands, received in the form of a series of bytes in a buffer in transmission mode of the communication port of the serial port type, into second commands, and to send the second commands via said communication port of the serial port type to devices of actuator or sensor types.

9. The electronic device according to claim 7, wherein said object-oriented data model is a COSEM model derived from the COSEM model (IEC 62056-6-2: 2017).

10. The electronic device according to claim 8, wherein at least one communication protocol is a DLMS protocol in the IEC 62056 standardised protocol set.

11. The electronic device according to claim 8, wherein at least one class of communication interface objects comprises attributes and methods for implementing communications via a serial port of the asynchronous type defined according to a so-called RS-422 communication standard or a so-called RS-485 communication standard.

12. The electronic device according to claim 8, the electronic device being an electricity consumption meter or a residential gateway configured for connecting an electricity consumption meter to a powerline communication network.

13. The communication system comprising at least one electronic device according to claim 1 and a remote server connected via a communication network.

14. A non-transitory storage medium embodying a computer program comprising a program code instructions for executing the steps of the method according to claim 1, when said program is executed by a processor of said electronic device or of a remote server connected to said electronic device.

15. (canceled)
